(19) United States
(12) Patent Application Publication
(10) Pub. No.: US 2005/0153059 A1
(43) Pub. Date: Jul. 14, 2005

(54) Partial plating method, partially-plated resin base, method for manufacturing multilayered circuit board

(76) Inventor: Yasuhiro Wakizaka, Tokyo (JP)

Correspondence Address: BIRCH STEWART KOLASCH & BIRCH, PO BOX 747, FALLS CHURCH, VA, 22040-0747, US

(21) Appl. No.: 10/505,733

(22) PCT Filed: Feb. 27, 2003
(86) PCT No.: PCT/JP03/02230

(30) Foreign Application Priority Data
Feb. 28, 2002 (JP) 2002-54807

(51) Int. Cl. B05D 5/12; H05K 3/00; C25D 5/54

(52) U.S. Cl. 427/96.1; 427/99.5; 205/183; 205/163

(57) ABSTRACT

Disclosed is a partial plating process for forming a patterned plating layer on a surface of a resin substrate. The partial plating process of the present invention comprises the following steps: subjecting the surface of the resin substrate to oxidation treatment, causing a compound, which has a structure capable of coordination to a metal atom or metal ion, to adhere in a pattered form on the oxidation-treated surface to form an initiator pattern, forming a plating layer on the initiator pattern by electroless plating, and allowing the plating layer to grow to a desired thickness, as needed. This invention also relates to partially plated resin substrates obtained by the process, and to a process for manufacturing multilayered circuit boards by using the partial plating process.

### TECHNICAL FIELD

This invention relates to a partial plating process for forming very narrow metal conductor lines on a surface of a resin substrate and also to partially plated resin substrates. Furthermore, this invention is concerned with a process for manufacturing a multilayered circuit board, which makes use of the partial printing process to form patterned, very narrow metal conductor lines (conductor circuit) on a surface of a resin substrate.

### BACKGROUND ART

Resin members, each of which includes a resin substrate with patterned, very narrow metal conductor lines formed on a surface thereof, such as multilayered circuit boards are used in semiconductor devices, semiconductor device mounting components, various panel displays, IC cards, optical devices and the like.

Plating processes are generally adopted for the formation of very narrow metal conductor lines (hereinafter may be referred to as “metal patterns”) in patterns such as the patterns of conductor circuits. Typical processes, which form a metal pattern by plating, include (1) a process for forming a metal pattern by applying electroless plating to the whole surface of a resin substrate, forming with a plating resist a resist pattern on the resultant electroless plating, causing a metal layer to grow by electrolytic plating via said resist pattern, removing the resist, and then removing the electroless plating at unnecessary areas by etching (semi-additive process) and (2) a process for depositing an electroless plating in a desired pattern on a resin substrate to form a metal pattern and then causing electrolytic plating metal to grow on the resin substrate as needed (full additive process).

The latter process which makes use of a pattern plating process is excellent in productivity, because in addition to the obviation of a step for the removal of an electroless plating, it does not cause metal corrosion with a chemical or the like which would otherwise be used for removing the electroless plating at unnecessary areas.

In the pattern plating, metallic patterns can be easily obtained by forming an initiator pattern (also referred to as “an electroless plating film”) comprised of a plating-inducing substance on a surface of a resin substrate and plating on this initiator pattern (e.g. Japanese Patent Laid-open No. 1995-263841).

A variety of investigations have been carried out on the plating-inducers to improve the adhesion to resin substrates and pattern shapes. The proposed plating-inducers include, for example, a conductive materials comprised of a mixture of a conductive polymer or a precursor thereof with water or a polar solvent (Japanese Patent Laid-open No. 2002-26014), a composition composed of a soluble palladium salt, a water-soluble solvent and water (Japanese Patent Laid-open Nos. 1995-131135 and 1995-245467) and a material containing a photosensitive palladium polymer chelate compound (Japanese Patent Laid-open No. 2000-147762).

Further, resin compositions for the plating inducers by combinations of (1) a low molecular weight compound having an N—H bond, an adhesive polymer having a C═C double bond, and a polybasic acid having a C═C double bond, (2) an adhesive polymer having a high N—H bond density, and a low molecular weight polybasic acid or a monobasic acid having a C═C double bond compatible therewith, (3) a resin component forming a N—H bond by a curing reaction and a polybasic acid having a C═C double bond, and (4) a resin component forming an N—H bond by a curing reaction and an adhesive polymer having a C═C double bond in the main chain thereof and a polybasic acid having a C═C double bond have been proposed.

These plating-inducers can easily ensure formation of metallic patterns on the resin substrates utilizing such plating inducers, however, improvement of firm adhesion between the metallic patterns and the resin substrates has been an important practical task to be solved.

In order to improve the firm adhesion, the surface of resin substrates is generally roughened by a physical or a chemical method so as to obtain a surface roughness, Ra, of several hundreds nm. However, roughening of the surface declines the accuracy of metallic patterns, and may causes noise in electrical signals in the case of circuit boards.

Therefore, development of a method to accomplish highly firm adhesiveness between the resin substrates and the metallic pattern without roughening of the surface of resin substrate has been desired.

### DISCLOSURE OF THE INVENTION

An object of the present invention is to provide a process for a partial plating to obtain partially plated resin substrates with excellent adhesiveness of the metallic pattern with the resin substrates.

The other object of the present invention is to provide partially plated resin substrates with excellent adhesiveness of the resin substrates and metallic patterns.

Further, the other object of the present invention is to provide a manufacturing process of a multilayered circuit board with excellent adhesiveness of the metallic patterns (conductor circuits) to the resin substrates (electrical insulating layers).

The present inventors have diligently investigated to solve the aforementioned tasks and invented a partial plating process for forming patterned plating layer on a surface of a resin substrate, which comprises subjecting the surface of the resin substrate to oxidation treatment, and then causing a compound, which has a structure capable of coordination to a metal atom or metal ion, to adhere in a patterned form on the oxidation-treated surface thereof to form an initiator pattern. The inventors found that plating the surface of the resin substrate with the initiator pattern formed thereon by electroless plating gives selectively plating layer in accordance with the form of said initiator pattern exhibiting excellent adhesiveness of said plating layer to the resin substrates.

As the resin substrate, one obtained by forming a curable resin composition, which comprises an insulating resin and a curing agent, and curing said curable resin composition is generally used. When the surface of the resin substrate is subjected to oxidation treatment, it is possible to remove a brittle layer, which is formed on the surface of the resin substrate by curing process, or a contaminant, which is adhered to it from a curing atmosphere, without roughening the surface of the resin substrate. Furthermore, oxidation of the surface of the resin substrate leads to effective action of the initiator pattern composed of a compound having a structure capable of coordination with a metal atom or metal ion adhered in a patterned form on the surface of the resin substrate and markedly improves adhesiveness between the plating layer formed thereon and the resin substrate. This invention is accomplished based on these findings.

Thus, the present invention provides a partial plating process for forming patterned plating layer on a surface of a resin substrate, which comprises the following steps:
(1) subjecting said surface of said resin substrate to oxidation treatment,
(2) causing a compound, which has a structure capable of coordination to a metal atom or metal ion, to adhere in a patterned form on said oxidation-treated surface of said resin substrate to form an initiator pattern,
(3) forming a plating layer on said initiator pattern by electroless plating, and
(4) allowing said plating layer to grow to a desired thickness by electroless plating or electrolytic plating as needed.

In addition, the present invention provides a partially plated resin substrate comprising a resin substrate with an oxidation treated surface and a plating layer formed on said oxidation-treated surface via an initiator pattern composed of a compound, which has a structure capable of coordination to a metal atom or metal ion, adhered in a patterned form.

Furthermore, the present invention provides a process for manufacturing a multilayered circuit board, which comprises the following steps:
I) forming a resin substrate layer over a surface of an inner layer substrate, which carries thereon an insulating layer with a conductor circuit formed on a surface thereof such that said conductor circuit is covered with said resin substrate layer,
II) subjecting said surface of said resin substrate layer to oxidation treatment,
III) causing a compound, which has a structure capable of coordination to a metal atom or metal ion, to adhere in a form of a pattern of said conductor circuit on said oxidation-treated surface of said resin substrate layer to form an initiator pattern,
IV) forming a plating layer on said initiator pattern by electroless plating, and
V) allowing said plating layer to grow to a desired thickness by electroless plating or electrolytic plating as needed.

### BRIEF DESCRIPTION OF THE DRAWINGS

FIG. 1 shows a cross sectional view of an example of the inner layer substrate used for the present invention.

FIG. 2 shows a cross sectional view of an example of a step of forming the resin substrate layer so as to cover the conductor circuit on the surface of inner layer substrate.

FIG. 3 shows a cross sectional view of an example of a step of forming via holes.

FIG. 4 shows a cross sectional view of an example of a step of oxidation treatment of the resin substrate surface.

FIG. 5 shows a cross sectional view of a step forming the initiator pattern by adhering a compound having a structure capable coordination with a metal atom or metal ion in a form of a pattern of a conductor circuit on a oxidation-treated surface.

FIG. 6 shows a cross sectional view of an example of a step of forming a plating layer on a initiator pattern.

### BEST MODE FOR CARRYING OUT THE INVENTION

1. A Partial Plating Process

The partial plating process of the present invention has the following steps:
Step 1: subjecting a surface of a resin substrate to oxidation treatment,
Step 2: causing a compound, which has a structure capable of coordination to a metal atom or metal ion, to adhere in a patterned form on the oxidation-treated surface of the resin substrate to form an initiator pattern,
Step 3: forming a plating layer on the initiator pattern by electroless plating, and
Step 4: allowing the plating layer to grow to a desired thickness by electroless plating or electrolytic plating as needed.
   Step 1

In the step 1, a surface of a resin substrate is subjected to oxidation treatment. The resin substrate used in step 1 may take any optional form of molded insulating resin such as film, sheet, plate, cylindrical or ball forms. The resin substrate is preferably one obtained by forming a curable resin composition, which comprises an insulating resin and a curing agent, and curing said curable resin composition.

(1) Insulating Resin

Any electrical insulating resin may be used for molding the insulating resin to give the resin substrate without particular restriction and practical examples include such as epoxy resins, maleimide resins, (meth)acrylic resins, diallyl phthalate resins, triazine resins, alicyclic olefin polymers, aromatic polyether polymers, benzocyclobutene polymers, cyanate ester polymers and polyimide resins.

Among these insulating resins, alicyclic olefin polymers, aromatic polyether polymers, benzocyclobutene polymers, cyanate ester polymers and polyimide polymers are preferable and alicyclic olefin polymers are more preferable.

Liquid crystalline polymers may also be used as the insulating resins. The liquid crystalline polymers such as polymers of aromatic or aliphatic dihydroxy compounds, polymers of aromatic or aliphatic dicarboxylic acids, polymers of aromatic hydroxylcarboxylic acids, aromatic diamines, aromatic hydroxyamines and aromatic aminocarboxylic acids may be enumerated.

No particular limit is defined in a weight average molecular weight (Mw) of the insulating resins, and those ranging preferably 10,000 to 1,000,000, more preferably 30,000 to 70,000 and particularly more preferably 50,000 to 500,000 can be selected for insulating polymers such as alicyclic olefin polymers. The insulating polymers having the weight average molecular weight of 10,000 to 1,000,000 are desirably present at a ratio of preferably 20% by weight or more, more preferably 30 to 100% by weight for the insulating resins contained in the curable resin compositions because of inhibition of roughening of resin substrate surface during pretreatment in electroless plating.

Combinations with insulating polymers other than those having the weight average molecular weight of 10,000 to 1,000,000, such as those with less than or beyond said above mentioned range may also be used.

In the present invention, the weight average molecular weight is expressed in terms of polystyrene or polyisoprene determined by gel permeation chromatography (GPC).

The alicyclic olefin polymers refer to unsaturated hydrocarbon polymers having alicyclic structure. The alicyclic structures include cycloalkane and cycloalkene structures, and the cycloalkane structures are preferable in view of mechanical strengths, heat resistances and so forth. Any alicyclic structures such as monocyclic and polycyclic (fused polycyclics, bridged rings or their combinations) may be used. No particular limit is defined in the carbon numbers constructing the alicyclic structures and generally 4 to 30, preferably 5 to 20, more preferably 5 to 15 carbon atoms are selected. Thus, highly balanced characteristic features such as mechanical strength, heat resistance and molding characteristics can be accomplished. The preferred alicyclic olefin polymers used in the present invention are those with thermosetting property in combination with a curing agent.

An alicyclic olefin polymer having a polar group are preferably used and the polar groups include hydroxyl, carboxyl, alkoxyl, epoxy, glycidyl, oxycarbonyl, carbonyl, amino, ester and carboxylic anhydride groups, and particularly carboxyl and carboxylic acid anhydride groups are more preferable.

Alicyclic olefin polymers may be obtained by, for example, (1) addition polymerization or ring opening polymerization of alicyclic olefins, and hydrogenation of unsaturated bond portion in the resultant polymers, if necessary or (2) addition polymerization of aromatic olefins followed by hydrogenation of the aromatic rings in the resultant polymers.

The alicyclic olefin polymers having a polar group may be obtained by, for example, (1) introduction of the polar group to alicyclic olefin polymers by modification reaction, (2) copolymerization of monomers having a polar group as polymerization components or (3) copolymerization of monomers having an ester group as polymerization components, followed by hydrolysis of the polar groups such as ester group in the copolymerized products.

Examples of alicyclic olefins that are used for obtaining alicyclic olefin polymers include: norbornene monomers such as bicyclo[2.2.1]-hept-2-ene (trivial name “norbornene”), 5-methyl-bicyclo[2.2.1]-hept-2-ene, 5,5-dimethyl-bicyclo [2.2.1]-hept-2-ene, 5-ethyl-bicyclo[2.2.1]-hept-2-ene, 5-butyl-bicyclo[2.2.1]-hept-2-ene, 5-hexyl-bicyclo[2.2.1]-hept-2-ene, 5-octyl-bicyclo[2.2.1]-hept-2-ene, 5-octadecyl-bicyclo[2.2.1]-hept-2-ene, 5-ethylidene-bicyclo[2.2.1]-hept-2-ene, 5-methylidene-bicyclo[2.2.1]-hept-2-ene, 5-vinyl-bicyclo[2.2.1]-hept-2-ene, 5-propenyl-bicyclo [2.2.1]-hept-2-ene, 5-methoxy-carbonyl-bicyclo[2.2.1]-hept-2-ene, 5-cyano-bicyclo[2.2.1]-hept-2-ene, 5-methyl-5-methoxycarbonyl-bicyclo[2.2.1]-hept-2-ene, 5-ethoxy-carbonyl-bicyclo[2.2.1]-hept-2-ene, bicyclo[2.2.1]-hept-5-enyl-2-methyl propionate, bicyclo[2.2.1]-hept-5-enyl-2-methyl octanate, bicyclo[2.2.1]-hept-2-ene-5,6-dicarboxylic anhydride, 5-hydroxymethylbicyclo[2.2.1]-hept-2-ene, 5,6-di(hydroxymethyl)-bicyclo[2.2.1]-hept-2-ene, 5-hydroxy-1-propylbicyclo[2.2.1]-hept-2-ene, 5,6-dicarboxy-bicyclo[2.2.1]-hept-2-ene, bicyclo[2.2.1]-hept-2-ene-5,6-dicarboxylic imide, 5-cyclopentyl-bicyclo [2.2.1]-hept-2-ene, 5-cyclohexyl-bicyclo[2.2.1]-hept-2-ene, 5-cyclohexenyl-bicyclo[2.2.1]-hept-2-ene, 5-phenyl-bicyclo [2.2.1]-hept-2-ene, tricyclo[4.3.0.1^{2,5}]deca-3,7-diene (trivial name “dicyclopentadiene”), tricyclo[4.3.0.1^{2,5}]deca-3-ene, tricyclo[4.4.0.1^{2,5}]undeca-3,7-diene, tricyclo[4.4.0.1^{2,5}]undeca-3,8-diene, tricyclo[4.4.0.1^{2,5}]undeca-3-ene, tetracyclo[7.4.0.1^{10,13}.0^{2,7}]-trideca-2,4,6-11-tetraene (alias name “1,4-methano-1,4,4a,9a-tetrahydrofluorene”), tetracyclo[8.4.0.1^{11,14}.0^{3,8}]-tetradeca-3,5,7,12,11-tetraene (alias name “1,4-methano-1,4,4a,5,10,10a-hexahydroanthracene”), tetracyclo [4.4.0.1^{2,5}.1^{7,10}]-dodeca-3-ene (trivial name “tetracyclododecene”), 8-methyl-tetracyclo[4.4.0.1^{2,5}.1^{7,10}]-dodeca-3-ene, 8-ethyl-tetracyclo[4.4.0.1^{2,5}.1^{7,10}]-dodeca-3-ene, 8-ethylidene-tetracyclo[4.4.0.1^{2,5}.1^{7,10}]-dodeca-3-ene, 8-ethylidene-tetracyclo[4.4.0.1^{2,5}.1^{7,10}]-dodeca-3-ene, 8-vinyl-tetracyclo[4.4.0.1^{2,5}.1^{7,10}]-dodeca-3-ene, 8-propenyl-tetracyclo[4.4.0.1^{2,5}.1^{7,10}]-dodeca-3-ene, 8-methoxycarbonyl-tetracyclo[4.4.0.1^{2,5}.1^{7,10}]-dodeca-3-ene, 8-methyl-8-methoxycarbonyl-tetracyclo [4.4.0.1^{2,5}.1^{7,10}]-dodeca-3-ene, 8-hydroxymethyl-tetracyclo, [4.4.0.1^{2,5}.1^{7,10}]-dodeca-3-ene, 8-carboxy-tetracyclo [4.4.0.1^{2,5}.1^{7,10}]-dodeca-3-ene, 8-cyclopentyl-tetracyclo [4.4.0.1^{2,5}.1^{7,10}]-dodeca-3-ene, 8-cyclohexyl-tetracyclo [4.4.0.1^{2,5}.1^{7,10}]-dodeca-3-ene, 8-cyclohexenyl-tetracyclo [4.4.0.1^{2,5}.1^{7,10}]-dodeca-3-ene, 8-phenyl-tetracyclo [4.4.0.1^{2,5}.1^{7,10}]-dodeca-3-ene, and pentacyclo[6.5.1.1^{3,6}.0^{2,7}.0^{9,13}]pentadeca-3,10-diene, pentacyclo[7.4.0.1^{3,6}.1^{10,13}.0^{2,7}]-pentadeca-4,11-diene; monocyclic cycloalkenes such as cyclobutene, cyclopentene, cyclohexene, 3,4-dimethylcyclopentene, 3-methylcyclohexene, 2-(2-methylbutyl)-1-cyclohexene, cyclooctene, 3a,5,6,7a-tetrahydro-4,7-methano-1H-indene, and cycloheptene; vinyl alicyclic hydrocarbon monomers such as vinylcyclohexene and vinylcyclohexane; and alicyclic conjugated diene monomers such as cyclopentadiene and cyclohexadiene.

Examples of aromatic olefins include styrene, α-methylstyrene, and divinylbenzene.

Alicyclic olefins and/or aromatic olefins may be used singly or in combination.

Alicyclic olefin polymers may include those obtained by copolymerizing alicyclic olefins and/or aromatic olefins with monomers copolymerizable therewith.

Examples of monomers that are copolymerizable with a alicyclic olefin or an aromatic olefin include: ethylene; α-olefins having 3 to 20 carbon atoms such as propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, and 1-eicosene; unconjugated dienes such as 1,4-hexadiene, 4-methyl-1,4-hexadiene, 5-methyl-1,4-hexadiene, and 1,7-octadiene. These monomers may be used singly or in combination.

A method for polymerizing alicyclic olefins and aromatic olefins and a method of hydrogenation performed as necessary are not particularly limited, but may be performed in accordance with well-known methods.

Examples of the alicyclic olefin polymers include (1) ring-opening polymers of norbornene monomers and their hydrogenated derivatives, (2) addition polymers of norbornene monomers, (3) addition polymers of norbornene monomers to vinyl compounds, (4) monocyclic cycloalkene polymers, (5) alicyclic conjugated diene polymers, (6) vinyl alicyclic hydrocarbon polymers and their hydrogenated derivatives, and (7) aromatic ring hydrogenated derivatives of aromatic olefin polymers. Among them, ring-opening polymers of norbornene monomers and their hydrogenated derivatives, addition polymers of norbornene monomers, addition polymers of norbornene monomers to vinyl compounds, and aromatic ring hydrogenated derivatives of aromatic olefin polymers are preferred, and hydrogenated derivatives of ring-opening polymers of norbornene monomers are most preferred.

The alicyclic olefin polymers may be used singly or in combination.

Among the alicyclic olefin polymers, most preferred ring-opening polymers of norbornene monomers and their hydrogenated derivatives are classified as the different polymers from the polyolefin resins obtained by copolymerizing olefins represented by CₙH₂ₙ due to the difference of their structures.

The methods for adjusting the weight average molecular weight of the alicyclic olefin polymers may be performed according to conventional methods, and include, for example, a method in which when undergoing the ring-opening polymerization of alicyclic olefins using a titanium-based or tungsten-based catalyst, a molecular weight modifier such as vinyl compounds or diene compounds is added in an amount approximately from 0.1 to 10 mol % relative to the total amount of the monomers. At this time, the use of smaller amount of the molecular weight modifier will provide polymers having relatively high weight average molecular weight, and larger amount will provide polymers having relatively low weight average molecular weight.

Examples of vinyl compounds that are used as a molecular weight modifier include: α-olefin compounds such as 1-butene, 1-pentene, 1-hexene, and 1-octene; styrene compounds such as styrene and vinyl toluene; ether compounds such as ethyl vinyl ether, isobutyl vinyl ether, and allyl glycidyl ether; halogen containing vinyl compounds such as allyl chloride; oxygen containing vinyl compounds such as allyl acetate, allyl alcohol, and glycidyl methacrylate; nitrogen containing vinyl compounds such as acrylamide.

Examples of diene compounds that are used as a molecular weight modifier include: unconjugated diene compounds such as 1,4-pentadiene, 1,5-hexadiene, 1,6-heptadiene, 2-methyl-1,4-pentadiene, and 2,5-dimethyl-1,5-hexadiene; and conjugated diene compounds such as 1,3-butadiene, 2-methyl-1,3-butadiene, 2,3-dimethyl-1,3-butadiene, 1,3-pentadiene, and 1,3-hexadiene.

The glass transition temperature of the alicyclic olefin polymers may be appropriately selected depending on intended use, and is generally 50° C. or higher, preferably 70° C. or higher, more preferably 100° C. or higher, most preferably 125° C. or higher.

(2) Curing Agent

Curing agents for use in the present invention include, but not limited to, for example, ionic curing agents, radical curing agents, and curing agents having both ionic and radical properties. Examples of curing agents include: nitrogen curing agents such as isocyanurate curing agents that contain an allyl group and an epoxy group and do not contain a halogen such as 1-allyl-3,5-diglycidylisocyanurate and 1,3-diallyl-5-glycidylisocyanurate; polyhydric epoxy compounds such as glycidylether expoxy compounds such as bisphenol A bis(ethyleneglycolglycidylether)ether, bisphenol A bis(diethyleneglycolglycidylether)ether, bisphenol A bis(triethyleneglycolglycidylether)ether, and bisphenol A bis(propyleneglycolglycidylether)ether, alicyclic epoxy compounds, and glycidyl ester epoxy compounds; dicarboxylic acid derivatives such as acid anhydrides and dicarboxylic acid compounds; and polyol compounds such as diol compounds, triol compounds, and polyhydric phenol compounds.

Among these curing agents, polyhydric epoxy compounds are preferred, and glycidyl ether epoxy compounds are particularly preferred in terms of enhancing crack resistance. The ratios of curing agents to the insulating resins may vary according to the kinds of insulating resins and curing agents, and generally 0.1 to 60 parts by weight and preferably 0.5 to 50 parts by weight of the curing agents to 100 parts by weight of the insulating resins are used.

(3) Curing Accelerators and Curing Aid:

Curing accelerators and curing aid may be used to stimulate curing reaction of insulating resins such as alicyclic olefin polymers and the curing agents. Tertiary amine compounds and boron trifluoride (BF₃) complex compounds are preferably used as curing accelerators for polyvalent epoxy compounds. Particularly application of the tertiary amine compounds improves properties for lamination, insulation-resistance, and resistances to heat and chemicals in micro-wiring (micro-conductor pattern).

Examples of tertiary amine compounds include acyclic tertiary amine compounds such as benzyldimethylamine, triethanolamine, triethylamine, tributylamine, tribenzylamine, dimethylformamide; compounds such as pyrazoles, pyridines, pyrazines, pirimidines, indazoles, quinolines, isoquinolines, imidazoles, triazoles and the like. Among them, imidazoles are preferred, and substituted imidazoles having substituted groups are most preferred.

Specific examples of substituted imidazole compounds include: alkyl-substituted imidazole compounds such as 2-ethylimidazole, 2-ethyl-4-methylimidazole, bis-2-ethyl-4-methylimidazole, 1-methyl-2-ethylimidazole, 2-isopropylimidazole, 2,4-dimethylimidazole, and 2-heptadecylimidazole; imidazole compounds substituted by a hydrocarbon group containing a cyclic structure such as an aryl group or aralkyl group such as 2-phenylimidazole, 2-phenyl-4-methylimidazole, 1-benzyl-2-methylimidazole, 1-benzyl-2-ethylimidazole, 1-benzyl-2-phenylimidazole, benzimidazole, 2-ethyl-4-methyl-1-(2″-cyanoethyl)imidazole, and 2-ethyl-4-methyl-1-[2′-(3″,5″-diaminotriazinyl)ethyl]imidazole. Among them, imidazoles having substituted groups including a ring structure are preferred in terms of compatibility with cycloaliphatic olefin polymers, and 1-benzyl-2-phenylimidazole is most preferred.

Curing accelerators are used singly or in combination. The loading of the curing accelerators is appropriately selected depending on intended use, and generally from 0.001 to 30 parts by weight, preferably from 0.01 to 10 parts by weight, more preferably from 0.03 to 5 parts by weight, relative to 100 parts by weight of insulating polymers.

Examples of curing aids include oxime-nitroso curing aids such as quinone dioxime, benzoquinone dioxime, and p-nitrosophenol; maleimide curing aids such as N,N-m-phenylene bismaleimide; allyl curing aids such as diallyl phthalate, triallyl cyanurate, and triallyl isocyanurate; methacrylate curing aids such as ethylene glycol dimethacrylate and trimethylol propane trimethacrylate; vinyl curing aids such as vinyl toluene, ethyl vinyl benzene, and divinyl benzene; and tertiary amine compounds such as 1-benzyl-2-phenylimidazole. In addition to these compounds, peroxides acting as curing aids for curing agents having an allyl group can be used.

(4) Other Components

The curable resin composition according to the present invention may formulate other components as necessary. For example, it is possible to formulate compounds having absorption in the wavelength region of laser beams used for forming holes such as via holes or through holes. For example, silica is used when using carbon dioxide gas laser, and ultraviolet absorbers are used when using ultraviolet laser (for example, UV-YAG laser or the like). Use of compounds having absorption in the wavelength region of laser beams facilitates the formation of holes by lasers and reduces the occurrence of a smear.

Specific examples of ultraviolet absorbers include salicylic acid compounds such as phenyl salicylate, p-tert-butylphenyl salicylate, p-octylphenyl salicylate; benzophenone compounds such as 2,4-dihydroxybenzophenone, 2-hydroxy-4-methoxybenzophenone, 2-hydroxy-4-octoxy-benzophenone, 2-hydroxy-4-dodecyloxybenzophenone, 2,2′-dihydroxy-4-methoxybenzophenone, 2,2′-dihydroxy-4,4′-dimethoxybenzophenone, 2-hydroxy-4-methoxy-5-sulfobenzophenone, bis(2-hydroxy-4-methoxybenzoylphenyl) methane; benzotriazole compounds such as 2-(2′-hydroxy-5′-methylphenyl)benzotriazole, 2-(2′-hydroxy-5′-tert-butylphenyl)benzotriazole, 2-(2′-hydroxy-3′,5′-di-tert-butylphenyl)-5-chlorobenzotriazole, 2-(2′-hydroxy-3′,5′-di-tert-amylphenyl)benzotriazole, 2-[2′-hydroxy-3′-(3″,4″,5″,6″-tetrahydrophthalimidomethyl)-5′-methylphenyl]benzotriazole, 2,2-methylenebis[4-(1,1,3,3-tetramethylbutyl)-6-(2H-benzotriazol-2-yl)phenol], 2-[2-hydroxy-3,5-bis(α,α-dimethylbenzyl)phenyl]benzotriazole; benzoate compounds such as 2,4-di-tert-butylphenyl-3′ 5′-di-tert-butyl-4′-hydroxybenzoate; cyanoacrylate compounds such as 2-ethylhexyl-2-cyano-3,3′-diphenylacrylate, ethyl-2-cyano-3,3′-diphenylacrylate; hindered amine compounds such as bis(2,2,6,6-tetramethylpiperidinyl4) sebacate; organic metal compounds such as nickel bis(octylphenyl)sulfide, [2,2′-thiobis(4-tert-octylphenolate)]-n-butylamine nickel; and inorganic compounds such as zinc oxide, tin oxide, titanium oxide, calcium carbonate, silica, and clay. Among them, benzotriazole compounds are preferable in terms of being excellent in compatibility with ring structure-containing polymers and stability during thermal curing.

The ultraviolet absorbers are formulated in an amount of generally from 0.1 to 30 parts by weight, preferably from 1 to 10 parts by weight, relative to 100 parts by weight of insulating polymers.

Additional components that may be used include flame retardants, flexible polymers, heat stabilizers, weathering stabilizers, antioxidants, leveling agents, antistatic agents, slip agents, antiblocking agents, antifog agents, lubricant, dye, pigment, natural oil, synthetic oil, wax, emulsion and fillers. The loadings may be appropriately selected within the range where objects of the present invention are not impaired.

(5) Resin Substrates

Curable resin compositions containing the insulating resins and the curing agents are used for molding the resin substrates in desired forms. For example, curable resin compositions may be molded by solution casting or fusion casting to give uncured or semi-cured film followed by heating and curing to give resin substrates in film forms. Other resin substrates may be molded in similar manners.

The resin substrates may be molded on the other substrates or supports such as an inner layer substrate. The curable resin composition is preferably molded in a layer by solution or fusion cast methods on these substrates or supports, and followed by curing of the curable resin composition. Layers of the curable resin compositions can be used in un-cured state or partially or semi-cured state by various histories of heat treatment during the formation of the layers.

The uncured layers of curable resin composition mean dissolution of the resin compositions substantially and wholly in a solvent capable of dissolution of the insulating resins constructing said resin composition layers. The semi-cured layers of curable resin composition mean partially cured resin that can be further cured by heating. The semi-cured curable resin composition layers are preferably in partially dissolved state in a solvent capable of dissolution of the insulating resin constructing said resin composition layers, or their swelling rate of 200% or over in comparison to the volume before immersion of the resin composition layers for 24 hours in the solvent.

Curing of the curable resin compositions is generally carried out by heating uncured or semi-cured resin substrates composed of the curable resin composition. The curing condition may be suitably selected by the kinds of insulating resins and the curing agents, and generally at temperature of 30 to 400° C., preferably 70 to 300° C. and more preferably 100 to 200° C. for generally 0.1 to 5 hours and preferably 0.5 to 3 hours. Any heating procedures can be used without restriction, for example, heating in an oven may be applied.

(6) Oxidation Treatment

The method for oxidizing the surface of the resin substrate is not particularly limited, and a method for bringing chemical substances into contact with the surface of the resin substrate, such as a method for using a solution of an oxidizing compound or a method for using a gaseous medium, is desirable, in that these methods do not roughen the surface of the base material.

Known oxidizing compounds having oxidation capability such as inorganic peroxides or organic peroxides can be used as an oxidizing compound. The inorganic peroxides such as permanganates, chromic anhydride, dichromates, chromates, persulfates, active manganese dioxide, osmium tetraoxide, hydrogen peroxide, periodates and ozone are enumerated. The organic peroxides such as dicumyl peroxide, octanoyl peroxide, m-chloroperbenzoic acid and peracetic acid are enumerated.

No particular limitation is imposed on the method for carrying out the oxidation treatment of the surface of the resin substrate with the oxidizing compound, and it includes, for example, a method in which an oxidizing compound is dissolved in a medium that can dissolve it to form a solution, as necessary, and then the solution is brought into contact with the resin substrate after cured. Examples of the medium to be used for dissolving the oxidizing compound include a neutral water, an aqueous alkaline solution such as aqueous NaOH solution, an aqueous acidic solution such as aqueous sulfuric acid solution, a neutral organic solvent such as ether and petroleum ether, a polar organic solvent such as acetone and methanol.

The method for bringing the oxidizing compound into contact with the surface of the resin substrate is not particularly limited, and may be any method such as, for example, a dipping method for immersing the resin substrate in a solution of the oxidizing compound, a liquid-laying method in which a solution of the oxidizing compound is laid on the surface of the substrate using surface tension, a spray process for spraying a solution of the oxidizing compound to the substrate.

The temperature and time for bringing these oxidizing compounds into contact with the surface of the resin substrate may be optionally set in consideration of the concentration and type of peroxides, contact methods and the like. The treatment temperature and time are generally 10 to 250° C. and preferably 20 to 180° C. for 0.5 to 60 minutes and preferably 1 to 30 minutes. Treatment temperature and time at below the above mentioned lower limit cause insufficient oxidation leading to poor improvement of adhesiveness of the initiator pattern formed on the plating layer. Treatment beyond their upper limits leads to the resin substrate surface brittle and impairs smoothness of the surface. Application of above mentioned treatment conditions removes brittle surface layer of the resin substrate prepared by curing the curable resin compositions and concomitant materials due to contact with curing environment.

Removal of oxidizing compounds after their contact with the surface of resin substrate is generally performed by washing with water. Adhesion of substances that can not be removed by washing solely with water may be treated by washing with a cleaning solution capable of dissolution of said substances or removed by contact with the other substances to convert them into water soluble substances and then washing with water. For example, contact with an aqueous alkaline solution of potassium or sodium permanganate is preferably followed by neutralization and reduction with an aqueous acidic solution such as a mixture of hydroxylamine sulfate and sulfuric acid to remove formed film of manganese dioxide.

Any oxidation treatment with a gaseous medium method can be carried out with known plasma treatment capable of radical formation or ionization of medium, for example, by reverse sputtering, that is plasma oxidation treatment by exchanging electrodes in conventional sputtering, or corona discharge. The gaseous media include air, oxygen, nitrogen, argon, water, carbon disulfide and carbon tetrachloride. When the medium stays liquid at treatment temperature, the oxidation is carried out under reduced pressure and its vaporization. When the medium stays gaseous form at treatment temperature, the oxidation is carried out under elevated pressure capable to form radical or ionization. The temperature and time for bringing plasma into contact with the resin material surface are optionally selected in consideration of kinds of gases and their flow rates. The treatment temperature and time are generally at 10 to 250° C., preferably at 20 to 180° C. for generally 0.5 to 60 minutes and preferably 1 to 30 minutes.

Roughness of the resultant oxidized surface of resin material, Ra, is generally 200 nm or less, preferably 100 nm or less and more preferably 80 nm or less. The roughness of surface, Ra, is an arithmetic mean roughness estimated according to the standard defined in JIS-B-0601.

Step 2

In the step 2, a compound, which has a structure capable of coordination to a metal atom or metal ion, is caused to adhere in a patterned form on the oxidation-treated surface of the resin substrate to form an initiator pattern.

Examples of compounds having a structure capable of coordinating to a metal atom or metal ion (hereinafter may be referred to “a coordination structure-containing compound”) include, but not limited to, compounds having functional groups capable of coordinating to a metal atom or metal ion such as an amino group, a thiol group, a carboxyl group or a cyano group; and compounds having unshared electron pairs such as heterocyclic compounds having coordination capability to a metal atom or metal ion.

Among them, heterocyclic compounds containing nitrogen atoms, oxygen atoms, or sulfur atoms are preferred, and those containing nitrogen atoms are more preferred. These heterocyclic compounds may further comprise functional groups capable of coordinating to metal atoms or metal ions. Heterocyclic compounds further comprising functional groups capable of coordinating to metal atoms or metal ions are preferable in that they provide higher pattern adhesion.

Examples of heterocyclic compounds containing an oxygen atom, sulfur atom, or nitrogen atom include pyrroles, pyrrolines, pyrrolidines, pyrazoles, pyrazolines, pyrazolidines, imidazoles, imidazolines, triazoles, tetrazoles, pyridines, piperidines, pyridazines, pyrimidines, pyrazines, piperazines, triazines, tetrazines, indoles, isoindoles, indazoles, purines, norharmanes, perimidines, quinolines, isoquinolines, cinnolines, quinosalines, quinazolines, naphthylidines, pteridines, carbazoles, acridines, phenazines, phenanthridines, phenanthrolines, furans, dioxolanes, pyrans, dioxanes, benzofurans, isobenzofurans, cormalines, dibenzofurans, flavones, trithianes, thiophenes, benzothiophenes, isobenzothiophenes, dithiins, thianthrenes, thienothiophenes, oxazoles, isoxazoles, oxadiazoles, oxazines, morpholines, thiazoles, isothiazoles, thiadiazoles, thiazines, and phenothiazines.

Among them, the following compounds are preferable in view of adhesiveness of the resin substrates and the plating layers.

(1) Imidazoles

Imidazoles; imidazoles having a thiol group such as 2-mercaptoimidazole, 2-mercaptomethylbenzoimidazole, 2-(2-mercaptoethyl)-benzoimidazole, and 2-mercapto-4-azabenzoimidazole; imidazoledithiocarboxylic acids such as imidazole-4-dithiocarboxylic acid, 2-methylimidazole-4-dithiocarboxylic acid, 2-ethylimidazole-4-dithiocarboxylic acid, 2-isopropylimidazole-4-dithiocarboxylic acid, 2-n-butylimidazole-4-dithiocarboxylic acid, 2-phenylimidazole-4-dithiocarboxylic acid, 4-methylimidazole-5-dithiocarboxylic acid, 2-phenyl-4-methylimidazole-5-dithiocarboxylic acid, 2-ethylimidazole-4-dithiocarboxylic acid, and 2-n-undecylimidazole-4-dithiocarboxylic acid; imidazoles having a carboxyl group such as imidazole-2-carboxylic acid, imidazole-4-carboxylic acid, 2-methylimidazole-4-carboxylic acid, 2-phenylimidazole-4-carboxylic acid, 2-methyl-4-methylimidazole-5-carboxylic acid, 2-(2-carboxyethyl)-benzoimidazole, and imidazole-2-carboxyamide; imidazoles having an amino group such as 1-(2-aminoethyl)-2-methylimidazole, 1-(2-aminoethyl)-2-ethylimidazole, 2-aminoimidazole sulfate, and 2-(2-aminoethyl)-benzoimidazole; imidazoles having a cyano group such as 2-cyanoimidazole, 4-cyanoimidazole, 4-methyl-5-cyanoimidazole, 2-methyl-5-cyanoimidazole, 2-phenyl-5-cyanoimidazole, 4-cyanomethylimidazole, 1-(2-cyanoethyl)-2-ethylimidazole, 1-(2-cyanoethyl)-2-ethyl-4-methylimidazole, 1-(2-cyanoethyl)-2-n-undecylimidazole, and 1-(2-cyanoethyl)-2-phenylimidazole; imidazoles having other groups such as 2-methylimidazole, 2-ethylimidazole, 2-isopropylimidazole, 2-n-propylimidazole, 2-n-butylimidazole, 2-phenylimidazole, 2-n-undecylimidazole, 2-n-heptadecylimidazole, 1,2-dimethylimidazole, 1-methyl-2-ethylimidazole, 1-benzyl-2-methylimidazole, 1-benzyl-2-ethylimidazole, 1-benzyl-2-phenylimidazole, 4-methylimidazole, 2,4-dimethylimidazole, 2-ethyl-4-methylimidazole, 2-n-butyl-4-methylimidazole, 2-phenyl-4-methylimidazole, 1-methylimidazole, 2-n-butyl-4-chloro-5-formylimidazole, 2-formylimidazole, 4-formylimidazole, 2-methyl-4-formylimidazole, 2-n-butyl-4-formylimidazole, 2-phenyl-4-formylimidazole, 4-methyl-5-formylimidazole, 2-ethyl-4-methyl-5-formylimidazole, 2-phenyl-4-methyl-5-formylimidazole, 2-methyl-4,5-diformylimidazole, 2-ethyl-4,5-diformylimidazole, 2-isopropyl-4,5-diformylimidazole, 2-n-propyl-4,5-diformylimidazole, 2-n-butyl-4,5-diformylimidazole, 2-n-undecyl-4,5-diformylimidazole, 2-nitroimidazole, 1-{2-hydroxy-3-(3-trimethoxysilylpropyloxy)}propylimidazole, 4-hydroxy-methylimidazole hydrochloride, 2-hydroxymethylimidazole hydrochloride, 2-methyl-4,5-dihydroxymethylimidazole, 2-ethyl-4,5-dihydroxymethylimidazole, 2-isopropyl-4,5-dihydroxymethylimidazole, 2-n-propyl-4,5-dihydroxymethyl-imidazole, 2-n-butyl-4,5-dihydroxymethylimidazole, 2-phenyl-4,5-dihydroxymethylimidazole, 2-n-undecyl-4,5-dihydroxymethylimidazole, benzoimidazole, benzoimidazole, 2-hydroxymethylbenzoimidazole, 2-chloromethylbenzo-imidazole, 1-{3-(3-trimethoxysilylpropyloxy)}-propylimidazole, 4-thiocarbamoylimidazole, 2-methyl-4-thiocarbamoylimidazole, 4-methyl-5-thiocarbamoylimidazole, 2-ethyl-4-methyl-5-thiocarbamoylimidazole, 2-phenyl-4-thiocarbamoylimidazole, 2-(2′-methylimidazolyl-4′)-benzoimidazole, 2-(2′-phenylimidazolyl-4′)-benzoimidazole, 4-azabenzoimidazole, 2-hydroxy-4-azabenzoimidazole, and 2-hydroxymethyl-4-azabenzoimidazole; or the like.

(2) Pyrazoles

Pyrazole; pyrazoles having a carboxyl group such as 4-carboxymethylpyrazole, 5-carboxymethylpyrazole, 1-methyl-4-carboxymethylpyrazole, 1-isopropyl-4-carboxymethylpyrazole, 1-benzyl-4-carboxymethylpyrazole, 1-methyl-5-carboxymethylpyrazole, 1-isopropyl-5-carboxymethylpyrazole, 1-benzyl-5-carboxymethylpyrazole, 1,3-dimethyl-4-carboxymethylpyrazole, 1-isopropyl-3-methyl-4-carboxymethylpyrazole, 1-benzyl-3-methyl-4-carboxymethylpyrazole, 1,3-dimethyl-5-carboxymethylpyrazole, 1-isopropyl-3-methyl-5-carboxymethylpyrazole, 1-benzyl-3-methyl-5-carboxymethylpyrazole, 1,5-dimethyl-4-carboxymethylpyrazole, 1-methyl-4-carboxymethyl-5-hydroxypyrazole, 1-methyl-4-chloro-5-carboxymethyl-pyrazole, 1-methyl-4,5-dicarboxymethylpyrazole, 1-methyl-4-cyano-5-carboxymethylpyrazole, 1-methyl-4-carboxymethyl-5-chloropyrazole, 1-isopropyl-4-carboxymethyl-5-methylpyrazole, 1-isopropyl-4-carboxymethyl-5-hydroxypyrazole, 1-isopropyl-4-chloro-5-carboxymethylpyrazole, 1-isopropyl-4,5-dicarboxymethylpyrazole, 1-isopropyl-4-dicarboxymethyl-5-chloropyrazole, 1-benzyl-4-carboxymethyl-5-hydroxypyrazole, 1-benzyl-4-carboxymethyl-5-methylpyrazole, 1-benzyl-4-chloro-5-carboxymethylpyrazole, 1-benzyl-4,5-dicarboxymethylpyrazole, 1-benzyl-4-carboxymethyl-5-chloropyrazole, 3-methyl-4-carboxymethyl-5-hydroxypyrazole, 3,5-dimethyl-4-carboxymethylpyrazole, 3-methyl-4-chloro-5-carboxymethylpyrazole, 3-methyl-4,5-dicarboxymethylpyrazole, 3-methyl-4-dicarboxymethyl-5-chloropyrazole, 1,3,5-trimethyl-4-carboxymethylpyrazole, 1-benzyl-3,5-dimethyl-4-carboxymethylpyrazole, 1,3-dimethyl-4-carboxymethyl-5-hydroxypyrazole, 1,3-dimethyl-4-chloro-5-carboxymethylpyrazole, and 1,3-dimethyl-4,5-dicarboxymethylpyrazole; pyrazoles having a cyano group such as 4-cyanopyrazole, 1-methyl-4-cyanopyrazole, 1-isopropyl-4-cyanopyrazole, 1-benzyl-4-cyanopyrazole, 1,3-dimethyl-4-cyanopyrazole, 1-isopropyl-3-methyl-4-cyanopyrazole, 1-benzyl-3-methyl-4-cyanopyrazole, 1,5-dimethyl-4-cyanopyrazole, 1-isopropyl-4-cyano-5-methylpyrazole, 1-isopropyl-4-cyano-5-hydroxypyrazole, 1-isopropyl-4-cyano-5-chloropyrazole, 1-benzyl-4-cyano-5-methylpyrazole, 1-benzyl-4-cyano-5-hydroxypyrazole, 1-benzyl-4-cyano-5-chloropyrazole, 3,5-dimethyl-4-cyanopyrazole, 3-methyl-4-cyano-5-hydroxypyrazole, 3-methyl-4-cyano-5-chloropyrazole, 1,3,5-trimethyl-4-cyanopyrazole, 1-benzyl-3,5-dimethyl-4-cyanopyrazole, 1,3-dimethyl-4-cyano-5-hydroxypyrazole; pyrazoles having an amino group such as 5-aminopyrazole, 1-methyl-5-aminopyrazole, 1-isopropyl-5-aminopyrazole, 1-benzyl-5-aminopyrazole, 1,3-dimethyl-5-aminopyrazole, 1-isopropyl-3-methyl-5-aminopyrazole, 1-benzyl-3-methyl-5-aminopyrazole, 1-methyl-4-chloro-5-aminopyrazole, 1-methyl-4-cyano-5-aminopyrazole, 1-isopropyl-4-chloro-5-aminopyrazole, 3-methyl-4-chloro-5-aminopyrazole, 1-benzyl-4-chloro-5-aminopyrazole, and 1,3-dimethyl-4-chloro-5-aminopyrazole; pyrazoles having any two or more amino groups, carboxyl groups, or cyano groups such as 1-methyl-4-carboxymethyl-5-aminopyrazole, 1-isopropyl-4-carboxymethyl-5-aminopyrazole, 1-benzyl-4-carboxymethyl-5-aminopyrazole, 3-methyl-4-carboxymethyl-5-aminopyrazole, 1,3-dimethyl-4-carboxymethyl-5-aminopyrazole, 1-isopropyl-4-cyano-5-aminopyrazole, 1-benzyl-4-cyano-5-aminopyrazole, 3-methyl-4-cyano-5-aminopyrazole, 1,3-dimethyl-4-cyano-5-aminopyrazole, 1-isopropyl-4-cyano-5-carboxymethylpyrazole, 1-benzyl-4-cyano-5-carboxymethylpyrazole, 3-methyl-4-cyano-5-carboxymethylpyrazole, and 1,3-dimethyl-4-cyano-5-carboxymethylpyrazole; pyrazoles having other groups such as 1-methylpyrazole, 1-isopropylpyrazole, 1-benzylpyrazole, 3-methylpyrazole, 5-methylpyrazole, 1,3-dimethylpyrazole, 4-chloropyrazole, 5-hydroxypyrazole, 5-chloropyrazole, 1-methyl-4-chloropyrazole, 1-isopropyl-4-chloropyrazole, 1,5-dimethylpyrazole, 1-methyl-5-hydroxypyrazole, 1-methyl-5-chloropyrazole, 1-isopropyl-5-methylpyrazole, 1-isopropyl-5-hydroxypyrazole, 1-isopropyl-5-chloropyrazole, 1-benzyl-5-methylpyrazole, 1-benzyl-5-hydroxypyrazole, 1-benzyl-5-chloropyrazole, 1,3-dimethyl-4-chloropyrazole, 1-benzyl-3-methyl-4-chloropyrazole, 1,3,5-trimethylpyrazole, 1,3-dimethyl-5-hydroxypyrazole, 1,3-dimethyl-5-chloropyrazole, 1-isopropyl-3-methyl-5-hydroxypyrazole, 1-benzyl-3,5-dimethylpyrazole, 1-benzyl-3-methyl-5-ethylpyrazole, 1-methyl-4-cyano-5-hydroxypyrazole, 1-methyl-4,5-dichloropyrazole, 1-methyl-4-cyano-5-chloropyrazole, 1-isopropyl-4-chloro-5-methylpyrazole, 1-isopropyl-4-chloro-5-hydroxypyrazole, 1-isopropyl-4,5-dichloropyrazole, 1-benzyl-4-chloro-5-methylpyrazole, 1-benzyl-4-chloro-5-hydroxypyrazole, 1-benzyl-4,5-dichloropyrazole, 3,5-dimethyl-4-chloropyrazole, 3-methyl-4-chloro-5-hydroxypyrazole, 3-methyl-4,5-dichloropyrazole, 1,3,5-trimethyl-4-chloropyrazole, 1-isopropyl-3,5-dimethyl-4-chloropyrazole, and 1,3-dimethyl-4-chloro-5-hydroxypyrazole; or the like.

(3) Triazoles

1,2,4-Triazole; triazoles having an amino group such as 1-amino-1,2,4-triazole, 2-amino-1,2,4-triazole, 1,2-diamino-1,2,4-triazole, 1-amino-2-hydroxy-1,2,4-triazole, 2,5-diamino-1,2,4-triazole, 2-amino-5-hydroxy-1,2,4-triazole, 1,2,5-triamino-1,2,4-triazole, and 1,2-diamino-5-hydroxy-1,2,4-triazole; triazoles having a thiol group such as 1-mercapto-1,2,4-triazole and 2-mercapto-1,2,4-triazole; triazoles having any two or more amino groups, thiol groups, or carboxyl groups such as 1-amino-2-mercapto-1,2,4-triazole, 1-mercapto-2-amino-1,2,4-triazole, 2-amino-5-mercapto-1,2,4-triazole, 1,2-diamino-5-mercaptotriazole, 1-mercapto-2,5-diamino-1,2,4-triazole, 1-mercapto-2-amino-5-mercapto-1,2,4-triazole, 1-mercapto-2-amino-5-hydroxy-1,2,4-triazole, 1,5-dimercapto-2-amino-1,2,4-triazole, and 3-amino-1,2,4-triazole-5-carboxylic acid; triazoles having other groups such as 2-hydroxy-1,2,4-triazole; or the like.

(4) Triazines

Triazines having an amino group such as 2-aminotriazine, 2,4-diaminotriazine, and 2,4-diamino-6-[6-[2-(2methyl-1-imidazolyl)ethyl]triazine]; triazines having a thiol group such as 2-anilino-4,6-dimercapto-s-triazine, 2-morpholyl-4,6-dimercapto-s-triazine, 2-monolauryl-4,6-dimercapto-s-triazine, 2,4,6-trimercapto-s-triazine, 2,4,6-trimercapto-s-triazine-monosodium salt, 2,4,6-trimercapto-s-triazine-trisodium salt; and triazines having an amino group and a thiol group such as 2-dibutylamino-4,6-dimercapto-s-triazine; or the like.

Among them, preferred are imidazoles, pyrazoles, triazoles, or triazines having an amino group, thiol group, carboxyl group, or cyano group.

Examples of preferred compounds having coordination structure include imidazoles such as imidazole, 2-methylimidazole, 2-ethyl-4-methylimidazole, 2-mercaptomethylbenzimidazole, 2-ethylimidazole-4-dithiocarboxylic acid, 2-methylimidazole-4-carboxylic acid, 1-(2-aminoethyl)-2-methylimidazole, 1-(2-cyanoethyl)-2-methylimidazole, 2-phenyl-4,5-dihydroxymethylimidazole, benzimidazole and 2-ethyl-4-thiocarbamoylimidazole; pyrazoles such as pyrazole and 3-amino-4-cyanopyrazole, triazoles such as 1,2,4-triazole, 2-amino-1,2,4-triazole, 1,2-diamino-1,2,4-triazole, and 1-mercapto-1,2,4-triazole, and triazines such as 2-aminotriazines, 2,4-diamino-6-[2-(2-methyl-1-imidazolyl)ethyl]triazine and 2,4,6-trimercapto-s-triazine-trisodium salt.

A preferred method to form the initiator pattern may show direct adhesion of a compound having coordination structure on the surface of the resin substrate in a pattern form. The adhesion is carried out by publicly known methods, for example, ink jet method of jet spraying of liquids, screen printing method of printing via a screen and dispenser coating method of direct coating of liquids. The adhesion procedure may be once or repetition of twice or more, if necessary.

Adhesion is generally carried out using solutions prepared by dissolution of the compound having coordination structure in water or an organic solvent, however, liquid compounds at temperature used for adhesion may be used as it is without dissolution in a solvent if they show no disturbance in the process of adhesion on the surface of resin substrate. Solvents for dissolution of compounds with coordination structure without dissolution of the resin substrates can be used without particular restriction and can suitably be selected from water and various organic solvents suitable for adhesion method.

Solvents for dissolution of the compounds with coordination structure include polar solvents of water, ethers such as tetrahydrofuran, alcohols such as ethanol and isopropanol, ketones such as acetone, a group of Cellosolve® such as Ethyl cellosolve® acetate, and their mixtures. There is no particular restriction for the concentration of compounds having coordination structure in the solution, however, generally 0.001 to 70% by weight and preferably 0.01 to 50% by weight is used.

Ink jet or screen printing preferably uses low volatile polar or high boiling point (90° C. or over) solvents to secure repetitive workability.

A thickening agent such as Aerosil® may be added to compounds with coordination structure or their solutions to give thixotropic property and favorable viscosity for adhesion method.

Temperature for adhesion may optionally be selected in consideration of boiling point, melting point, operability and productively of compounds with coordination structure and solvents used, and generally at 10 to 100° C. and preferably 15 to 65° C. are used.

Removal of excessive compound with coordination structure after its adhesion on the surface of the resin substrate may be carried out by washing the surface with water, blowing of an inert gas such as nitrogen or drying in an oven generally at 30 to 180° C. and preferably 50 to 150° C. preferably for one minute or longer and more preferably 5 to 120 minutes.

The compounds with coordination structure penetrate in the oxidized surface of resin substrate and enhance interface adhesion between the resin substrate and electroless plating layer.

Step 3

In the step 3, electroless plating selectively forms plating layer on the initiator pattern on the surface of the resin substrate.

Plating with the electroless plating is generally carried out by adhesion and activation of a catalyst such as silver, palladium, zinc and cobalt on the resin substrate. The catalyst for plating adheres on the initiator pattern formed on the surface of the resin substrate. There is no particularly limited method for adhesion and activation of the plating catalyst and includes, for example, a method in which the resin substrate is brought into contact with an aqueous potassium permanganate solution or an aqueous sodium permanganate solution as necessary; subjected to neutralization and reduction by an aqueous acidic solution such as a mixed solution of hydroxyamine sulfate and sulfuric acid or the like; and then immersed in a liquid in which a metallic compound of silver, palladium, zinc, cobalt or the like, or salts or complexes thereof is dissolved in water or in an organic solvent such as alcohol or chloroform in a concentration of 0.001 to 10% by weight (may contain acid, alkali, a complexing agent, reducing agent or the like, as necessary) to reduce metal. The solution may optionally further contain an acid, an alkali, a complexing agent, a reducing agent and so forth.

A larger amount of the catalyst is adsorbed with the initiator pattern on the resin substrate and then, preferably removed from areas without initiator pattern to increase accuracy of the patterned plating layer to give conductor circuit. The removal of unnecessary catalyst is generally carried out by washing with water after adhesion and activation of the catalyst.

Molding of the resin substrates utilizing the curable resin compositions containing an insulating polymer such as alicyclic olefin polymers with the weight average molecular weight of 10,000 to 1,000,000 highly inhibits roughening in catalyst adsorption treatment before formation of the plating layer.

Thus, the activated catalyst is attached on the initiator pattern of the resin substrate and then brought into contact with an electroless plating solution to perform electroless plating.

No particular restriction is required for the electroless plating solution used for electroless plating and known autocatalytic electroless plating solutions are preferably used. The electroless plating solutions are, for example, an electroless copper plating solution using ammonium hypophosphite or hypophosphorous acid, ammonium borohydride, hydrazine and formaldehyde as a reducing agent, an electroless nickel-phosphorus plating solution using sodium hypophosphite as a reducing agent, an electroless nickel-boron plating solution using dimethylamine borane as a reducing agent, an electroless palladium plating solution, an electroless palladium-phosphorus plating solution using sodium hypophosphite as a reducing agent, an electroless gold plating solution, an electroless silver plating solution, and an electroless nickel-cobalt-phosphorus plating solution using sodium hypophosphite as a reducing agent can be used for the electroless plating.

After the electroless plating, the surface of the resin substrate can also be brought into contact with an anti-corrosive agent to be subjected to anti-corrosive treatment.

Step 4

In the step 4, the plating layer is allowed to grow to a desired thickness by electroless plating or electrolytic plating as needed. The patterned plating layer is generally used for a dielectric circuit and preferably allowed to growth to the required thickness for the dielectric circuit.

The thickness (total thickness) of plating layer in the step 3 and the step 4 which is conducted as needed, can be suitably defined according to the requirement and is generally 0.5 to 100 μm, preferably 1 to 70 μm and particularly preferably 2 to 50 μm. The plating layers in steps 3 and 4 may be made from the same or different metals. When the step 4 was performed, the aforementioned rust proofing treatment is generally performed after the step 4.

Additional Step

The resin substrate is preferably subjected to heat treatment at 50 to 350° C., preferably 80 to 250° C. for 0.1 to 10 hours, preferably for 0.1 to 5 hours after formation of patterned plating layer on the resin substrate by the electroless plating to improve the adhesiveness between the resin substrate and the plating layer.

The heat treatment is preferably carried out in an inert gas atmosphere such as nitrogen or argon. Furthermore, the resin substrate may be pressurized with a presser in heat treatment, if necessary.

The partially plated resin substrate with patterned plating layer on the surface thereof can be produced by such steps as shown above.

2. Partially Plated Resin Substrate

The partially plated resin substrate of the present invention is the partially plated resin substrate with formed a plating layer via the initiator pattern composed of the compound capable of coordination with the metal atom or ion adhered in a patterned form on the oxidation-treated surface of the resin substrate.

Such partially plated resin substrates can be manufactured by application of the aforementioned partial plating. The partially plated resin substrate may be used singly, however, generally used in combination with the other substrates to give resin members such as multilayered circuit board.

3. Process for Manufacturing Multilayered Circuit Board

The manufacturing process of the multilayered substrate of the present invention comprises of the following steps:
Step (I): forming a resin substrate layer over a surface of an inner layer substrate, which carries thereon an insulating layer with a conductor circuit formed on a surface thereof such that the conductor circuit is covered with the resin substrate layer,
Step (II): subjecting the surface of the resin substrate layer to oxidation treatment,
Step (III): causing a compound, which has a structure capable of coordination to a metal atom or metal ion, to adhere in a form of a pattern of the conductor circuit on the oxidation-treated surface of the resin substrate layer to form an initiator pattern,
Step (IV): forming a plating layer on the initiator pattern by electroless plating, and
Step (V): allowing the plating layer to grow to a desired thickness by electroless plating or electrolytic plating as needed.
   Step (I)

In the step (I), a resin substrate layer is formed over a surface of an inner layer substrate, which carries thereon an insulating layer with a conductor circuit formed on a surface thereof such that the conductor circuit is covered with the resin substrate layer.

(1) Inner Layer Substrate

The inner layer substrate used in the step (I) of the present invention is an inner layer substrate with a conductor circuit formed on a surface thereof. The inner layer substrate is formed with a conductor circuit on a surface of an insulating layer, and generally has a structure with conductor circuits formed on both sides of the insulating layer and used as a core of multilayered circuit board.

Examples of the inner layer substrate may be enumerated such as printed wiring board and silicon wafer substrate. The inner layer substrate may have various structures such as through holes other than conductor circuit. The electrical insulating layer may be a single layer or a laminate prepared by laminating glass cloths (prepregs) impregnated with resins. The inner base layer plate may be partially laminated.

Thickness of the inner base layer plate is preferably 50 μm to 2 mm, more preferably 60 μm to 1.6 mm, and further more preferably 100 μm to 1 (one) mm.

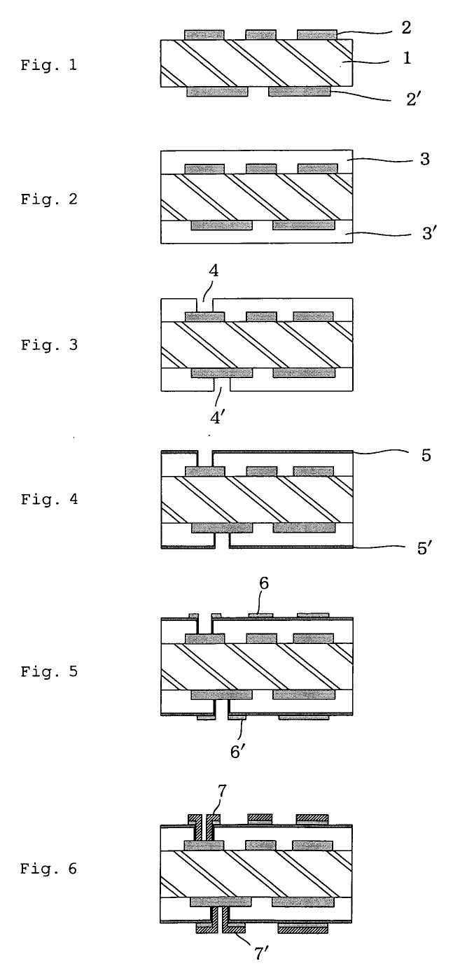

The inner layer substrate is preferably formed with conductor circuits 2,2′ on both sides of insulating layer 1 as shown in FIG. 1. The completed multilayer circuit board may preferably be symmetrical for both sides so as to minimize its warpage and reduces its influence in soldering.

The insulating layer constructing the inner layer substrate is preferably molded from resin composition mainly composed of insulating resin having electric insulating property. Any insulating resin may be used without restriction and includes, for example, alicyclic olefin polymers, epoxy resins, maleimide resins, (meth)acrylic resins, diallyl phthalate resin, triazine resins, aromatic polyether polymers, cyanate ester polymers and polyimide resins. Generally, resin substrate is molded using the curable resin compositions containing these insulating resins and curing agents, and the mixed composition is cured to give insulating layer. The inner layer substrate may contain glass fiber or resin fiber to improve strength. Materials for constructing conductor circuit layer of the inner layer substrate are generally conductive metal.

(2) Resin Substrate Layer

Resin substrate layer is formed so as to cover the conductor circuit on the surface of the inner layer substrate. The resin substrate layer is preferably prepared by curing the curable resin composition layer containing the insulating resin and the curing agent. Formation of the resin substrate layers on both sides of the inner layer substrate is carried out by formation of the curable resin composition layer on both sides of the insulating layer 1 of the inner layer substrate so as to cover corresponding conductor circuits 2 and 2′ as shown in FIG. 2.

The curable resin composition still remains un-cured or semi-cured states when said curable resin composition layer is formed. There is no particular method for the formation of the curable resin composition layer (thermosetting resin composition layer) on the surface of the inner layer substrate. Methods of forming a thermosetting resin composition layer on the surface of an inner layer substrate preferably include, but not limited to, a method of forming the resin composition layer by bonding together films (including sheets) of a curable resin composition containing an insulating polymer and a curing agent so as to be in contact with the conductor circuit on the inner layer substitute (method 1), or a method of forming an uncured or a semi-cured resin composition layer by coating a solution of a curable resin composition containing an insulating polymer and a curing agent on the surface of the inner layer substitute and drying it (method 2).

Formation of the curable resin composition layer using the film of the curable resin composition (Method 1) is more preferable as the plating layer formed on the resin substrate layer obtained by curing the curable resin composition layer gives highly homogenous interface adhesiveness of the resin substrate layer and the plating layer.

(3) Curable Resin Composition Film

The curable resin composition film used in the method 1 is generally molded by the solution or fusion cast method of the curable resin composition. Molding of film by the solution cast method is carried out by coating of an organic solvent solution containing an insulating resin and a curing agent (varnish) followed by drying and removal of the solvent.

Supporting bodies used for the solution cast method include a resin film (carrier film) and a metal foil. A thermoplastic resin film is preferable for the carrier film and practically polyethylene terephthalate films, polyethylene naphthalate films, polypropylene films, polyethylene films, polycarbonate films, polyallylate films and nylon films can be enumerated. Among these carrier films, polyester films such as polyethylene terephthalate films and polyethylene naphthalate films are preferable in view of heat resistance, drug resistance and peeling after lamination.

Metal foils for the support body made of such as copper, aluminum, nickel, chromium, gold, silver and the like can be enumerated. Among them, electrolytic or rolled copper foil can be used at low cost and is preferable. No particular thickness is defined for the supporting body and generally 1 to 150 μm, preferably 2 to 100 μm, more preferably 3 to 50 μm are selected in view of workability.

Any method can be used for preparation of a varnish, for example, components composing the curable resin composition are mixed with an organic solvent. Conventional mixing methods are used, for example, stirring using a stirring bar and a magnetic stirrer, high speed homogenizers, dispersion, planetary stirrers, biaxial stirrers, ball mills and triple roll stirrers can be used. Their mixing temperature is out of the range affecting on workability due to reaction with the curing agent and temperature below boiling point of the organic solvent used for mixing are preferable in view of safety.

Organic solvents of aromatic hydrocarbons such as toluene, xylene, ethylbenzene and trimethylbenzenes; aliphatic hydrocarbons such as n-pentane, n-hexane and n-heptane; alicyclic hydrocarbons such as cyclopentane and cyclohexane; halogenized hydrocarbons such as chlorobenzene, dichlorobenzenes and trichlorobenzenes; ketones such as methyl ethyl ketone, methyl isobutyl ketone, cyclopentanone and cyclohexanone can be enumerated. These organic solvents can be used singly or in combinations of two or more solvents. Among these organic solvents, mixed organic solvents of non polar organic solvents such as aromatic hydrocarbons and alicyclic hydrocarbons, and polar organic solvents such as ketones are preferable for their favorable embedding property in very narrow conductor lines (conductor circuit) without bubbling. Their mixing ratios are suitably selected and generally within the weight ratios of 5:95 to 95:5, preferably 10:90 to 90:10, and more preferably 20:80 to 80:20.

The amount of organic solvents used is suitably selected to satisfy the purpose such as control of thickness and improvement of smoothness, and concentration of solid components in the varnish is generally 5 to 70% by weight, preferably 10 to 65% by weight and more preferably 20 to 60% by weight.

The coating methods include such as dip coat, roll coat, curtain coat, die coat and slit coat. The drying and removal conditions of organic solvents are suitably selected from the kind of organic solvent used. The drying temperature and time are generally 20 to 300° C. and preferably 30 to 200° C. for 30 seconds to an hour and preferably 1 to 30 minutes.

The thickness of the curable resin composition film is generally 0.1 to 150 μm, preferably 0.5 to 100 μm and more preferably 1 to 80 μm. Single formation of the film on a supporting body and release of the film from the supporting body solely give the curable resin composition film.

(4) Formation of the Resin Substrate Layer

For bonding the film of the curable resin composition to the surface of the inner layer substrate in step (1), generally, the film with a support is overlapped such that the film is brought into contact with the conductor circuit and subjected to thermo-compression bonding using a pressure machine such as a pressure laminator, a press, a vacuum laminator, a vacuum press, or a roll laminator to combine the both so that substantially no air-gap is present at the interface between the surface of the inner layer substrate and the film. The thermo-compression bonding is preferably performed under vacuum to improve embedding properties to the micro-wiring and to suppress generation of blisters or the like. The temperature of adhesion by heating is generally at 30 to 250° C. and preferably at 70 to 200° C. under pressures of 10 kPa to 20 MPa and preferably 100 kPa to 10 MPa for 30 seconds to five hours and preferably one minute to three hours. Adhesion by heating is generally carried out under reduced pressure of 100 kPa to one Pa and preferably 40 kPa to 10 Pa.

When the curable resin composition layer is formed by using the film of the curable resin composition, the surface of an inner layer substrate on which a conductor circuit is formed is preferably pre-treated before the films of a curable resin composition are bonded together in order to improve the adhesive strength between the inner layer board on which a conductor circuit is formed and an electrical insulating layer. The pre-treatment methods include (1) a method of bringing an alkaline aqueous solution of sodium chlorite, permanganic acid or the like into contact with the surface of the inner layer board to roughen the surface, (2) a method of oxidizing the surface by an alkaline aqueous solution of potassium persulfate, an aqueous solution of potassium sulfide-ammonium chloride or the like and then reducing it, (3) a method of depositing the plating on the part of the conductor circuit on the inner layer board to roughen it, (4) a method of forming a primer layer on the surface of the inner layer board by a thiol compound, a silane compound or the like.

Among these treatment methods, a method of forming a primer layer using thiol compounds such as 2-di-n-butylamino-4,6-dimercapto-s-triazine is suitable in that when the conductor circuit is formed of copper, corrosion of the copper is prevented and high adhesion is obtained.

The films of the curable resin composition to be bonded together to the inner layer substrate may be two or more. For example, the inner layer substrate having a film of the curable resin composition laminated thereon may be laminated with a different film, such that it is brought into contact with the film of the curable resin composition, for the purpose of improving the flatness of the resin substrate layer or increasing the thickness of the resin substrate layer. When films are laminated by bonding a plurality of films together to the inner layer substrate, it is the surface of the film laminated last that is subjected to oxidation treatment in the following step (II).

Formation of the curable resin composition layer by coating method can be carried out by direct coating of the varnish composed of the curable resin composition on the inner layer substrate and drying. The methods and conditions for coating and drying may be similar with those of formation of the curable resin composition film.

The resin substrate layer is preferably prepared by curing the curable resin composition layer. Curing of the curable resin composition layer is carried out by heating un-cured or semi-cured curable resin composition layer. The curing conditions are suitably selected for the kinds of insulating resins and curing agents, and generally at 30 to 400° C., preferably at 70 to 300° C. and more preferably at 100 to 200° C. for generally 0.1 to 5 hours and preferably 0.5 to 3 hours. No particular method for heating is defined and, for example, heating in an oven may be applied.

The resin substrate layer formed on the inner layer substrate provides a new insulating layer and the patterned plating layer formed on the resin substrate layer provides a new conductor circuit.

(5) Formation of Via Holes

Via holes are formed to conduct between the conductor circuit of the inner layer substrate and the conductor circuit (patterned plating layer) on the new insulating layer (resin substrate layer) formed on the inner layer substrate to give a multilayered circuit board.

Formation of via holes in the resin substrate layer is carried out by masking for pattern formation of via holes in the curable resin composition layer before curing to photo-set the resist and removal of un-cured parts with photolithography technique. In this case, curing of the curable resin composition is performed after formation of via holes.

Formation of openings of via holes in the resin substrate layer after curing the curable resin composition is performed by physical treatment methods such as drilling, laser and plasma etching. Laser treatment such as carbon dioxide gas laser, excimer laser and UV-YAG laser are preferable to give more fine via holes without decline of characteristic features of resin substrate layer is preferable.

Step (II)

In the step (II), the surface of the resin substrate layer is subjected to oxidation treatment. Similar methods as the above described methods for oxidation treatment in the partial plating process can be adopted as the methods for the oxidation treatment. Inner walls of via holes are also subjected to oxidation treatment when the via holes were formed.

Step (III)

In the step (III), the compound having a structure capable of coordination with a metal atom or ion (coordination structure containing compound) is adhered in a pattered form on the oxidation-treated surface of the resin substrate layer to give an initiator pattern. The form of the initiator pattern is that of desired conductor circuit. Similar methods as the above described methods for forming the initiation pattern in the partial plating process can be adopted as the methods for forming the initiation pattern. Adhesion of the coordination structural compounds on the inner wall of via holes is desirable for the formation of via holes.

Step (IV)

In the step (IV), electroless plating is carried out to selectively form a plating layer on the initiator pattern of resin substrate layer. The similar method as the above described methods for forming the plating layer in the partial plating process can be adopted as the method for forming the plating layer by the electroless plating. The plating layer is also formed in the inside wall of via holes in case of formation of via holes.

Step (V)

In the step (V), the plating layer formed in the step (IV) is grown to a desired thickness by electroless or electrolytic plating as needed. The similar method as the above described methods in the partial plating process can be adopted as the method for this step.

Manufacturing of multilayered circuit board is explained referring the drawings. FIG. 1 shows one example of cross sectional drawing of the inner layer substrate with conductor circuits 2 and 2′ formed on both sides of the insulating layer 1. FIG. 2 shows one example of cross sectional drawing of a step forming the resin substrate layers 3 and 3′ over the surface of the inner layer substrate 1 such that the conductor circuits 2 and 2′ on the surface of the inner layer substrate 1 is covered with the resin substrate layer. FIG. 3 shows one example of cross sectional drawing of a step forming via holes 4 and 4′ in the resin substrate layers 3 and 3′.

FIG. 4 shows one example of cross sectional drawing of a step oxidizing the surfaces of resin substrate layers 3 and 3′. In FIG. 4, the oxidatively treated surfaces 5 and 5′ are shown in layers, however, practical oxidation treatment is limited and performed on the surfaces of the resin substrate layers and forms no layer.

FIG. 5 shows cross sectional drawing of a step forming initiator patterns 6 and 6′ by pattern-like adhesion of the conductor circuit of compounds capable of coordination to a metal atom or ion (coordination structure containing compounds) on the oxidized surfaces 5 and 5′. FIG. 5 shows the initiation patterns 6 and 6′ as layers with substantial thickness for the explanation. FIG. 6 shows one example of cross sectional drawing of a step forming plating layers 7 and 7′ on the initiator patterns 6 and 6′.

FIG. 1 through 6 show steps to form resin substrate layers on both sides of the inner layer substrate having conductor circuits on both sides and further formation of pattern-like plating layer (a new conductor circuit) on said resin substrate layer. However, the resin substrate layer and the plating layer may be formed on only one side of the inner layer substrate, if necessary.

Steps similar to steps (I) to (V) are repeated as needed until one or more resin substrate layers, each of which comprises an inner layer substrate and a plating layer formed in a form of a pattern of a conductor circuit formed on at least one side of said inner layer substrate, are formed one over the other as many as desired. Multilayer circuit boards such as a multilayer printed wiring board generally have three or more “insulating layer/conductor circuit” layers and some exceeds 70 layers. A desired number (number of layers) of “resin substrate layer/patterned plating layer” may be formed according to the present invention. The resin substrate layer is an insulating layer and the pattered plating layer is a conductor circuit.

The partially plated resin substrate and multiple layered circuit board with equipped resin substrate layer having partially plated layer obtained by the present invention can be used, for example, as printed wiring assembly for semiconductor devise mounting parts, various panel indicator apparatuses, IC cards and photo devices.

### EXAMPLES

The present invention is practically explained by examples and comparative examples. The term “parts” and “%” in the examples are expressed by weight except otherwise stated.

The evaluation methods carried out in the examples are as follows.

(1) Molecular Weight [Weight Average Molecular Weight (Mw), Number Average Molecular Weight (Mn)]

Determined by gel permeation chromatography (GPC) using toluene as a solvent and expressed as corresponding value of polystyrene.

(2) Hydrogenation Rate and Maleic (anhydride) Residue Content Rate

Hydrogen addition (hydrogenation) rate to the mole number of unsaturated bond in polymers before hydrogenation and molar ratios (content of carboxyl group) of maleic (anhydride) residue to total number of monomer unit in polymer were determined by ¹H-NMR spectra.

(3) Glass Transition Temperature (Tg)

Determined by differential scanning calorimeter (DSC):

(4) Average Roughness of Surface (Ra)

Determined and evaluated with tapping mode in the air using an atomic force microscope (AFM) [Nanoscope 3a (manufactured by Digital Instrument)] using Si single crystal strip cantilver (spring constant=20 N/m, length 125 μm). Ra is an arithmetic average roughness defined by JIS-B-0601.

(5) Evaluation of Pattern Adhesiveness

The evaluation pattern of adhesiveness defined in JIS-C-5012-8.5 for multiple layered circuit board formed at the outermost layer was examined after allowing to stand at 25° C. and in 65% relative humidity (RH) for 24 hours. Then adhesiveness of plating was examined according to JIS-C-5012-8.5 and peeling and lifting of the plating layer were observed with naked eyes. No peeling or lifting was judged “good” and observation of peeling or lifting was judged “poor”.

(6) Evaluation of Patterning:

One hundred wiring patterns were formed with wiring width of 30 μm, distance between wiring of 30 μm, and length of wiring of 5 cm, and observed with an optical microscope. No disturbance in the 100 wiring pattern is judged “excellent” and those with slight disturbance such as lifting without defect such as peeling were judged “good” and those with defects were judged “poor”.

### Example 1

1. Step for Formation of Resin Substrate Layer

Ring opening and polymerization were carried out for 8-ethyl-tetracyclo[4.4.0.1^{2,5}.1^{7,10}]dodeca-3-ene. Then, the resultant ring opened polymer was hydrogenated to give a hydrogenated polymer of the number average molecular weight (Mn)=31,2000, the weight average molecular weight (Mw)=55,800 and Tg=about 140° C. The hydrogenation rate of the resultant polymer was 99% or over.

In 250 parts of tert-butylbenzene, 100 parts of the resultant polymer, 40 parts of maleic anhydride and five parts of dicumyl peroxide were dissolved and caused to react at 140° C. for six hours. The resultant reaction product solution was poured in 1,000 parts of isopropyl alcohol to coagulate the reaction product to give a maleic acid modified hydrogenated polymer. The modified hydrogenated polymer was dried in vacuo at 100° C. for 20 hours. The molecular weight of modified hydrogenated polymer was Mn=33,200, Mw=68,300 and Tg=170° C. The content rate of maleic (anhydride) residue was 25 mole %.

In a mixture of 215 parts of xylene and 54 parts of cyclopentanone, 100 parts of the aforementioned modified hydrogenated polymer, 40 parts of bisphenol A bis(propyleneglycol glycidyl ether)ether, five parts of 2-[2-hydroxy-3,5-bis(α,α-dimethylbenzyl)phenyl]benztriazole and 0.1 part of 1-benzyl-2-phenylimidazole were dissolved to give a varnish of curable resin composition.

Said varnish was coated on a polyethylene naphthalate film (carrier film) of 300 mm square and 40 μm thickness using a die coater and then dried at 120° C. for 10 minutes in a nitrogen oven to give a dry film with equipped a 35 μm thickness carrier film.

While a 0.1% isopropyl alcohol solution of 2-di-n-butylamino-4,6-dimercapto-s-triazine was prepared and an inner layer substrate with micro etching treated conductor layers of width of wiring and distance between wirings 50 and 18 μm, respectively, on the surface (obtained from copper laminated substrate on both sides prepared by immersion of glass filler and a varnish containing halogen free epoxy resin) was immersed at 25° C. for one minute, and then dried at 90° C. for 15 minutes in a nitrogen purged oven to give a primer layer.

The dry film with equipped the carrier film was laminated on both sides of the inner layer substrate so as to place the curable resin composition film on the inner side. The laminated film was primarily and thermally pressed and adhered under reduced pressure at 200 Pa, at 110° C. and 0.5 MPa for 60 seconds using a vacuum laminator with equipped heat resistant rubber press plates on both sides. Then the resultant film was secondarily and thermally pressed under reduced pressure at 200 Pa, at 140° C. and 1.0 MPa for 60 seconds using a vacuum laminator with equipped heat resistant rubber press plates covered with metallic press plate on both sides to laminate the curable resin composition film.

The polyethylene naphthalate film or carrier film was solely peeled off from the inner layer substrate with laminated the curable resin composition film. Determination of the surface roughness of the resin substrate layer showed Ra=14 nm.

The inner layer substrate with laminated the curable resin composition film was allowed to stand in a nitrogen purged oven at 170° C. for 60 minutes to cure the curable resin composition to give a laminated plate with formed resin substrate layer (insulating layer) on the inner layer substrate. Via holes of 30 μm diameter connecting layers were prepared in the resin base layer (insulating layer) of the resultant laminated plate using the third harmonic of UV-YAG laser to give a multilayered substrate with via holes.

2. Step for Oxidation Treatment

The above mentioned multilayered substrate with via holes was immersed with shaking in an aqueous solution containing 60 g/L of permanganic acid and 28 g/L of sodium hydroxide at 80° C. for 15 minutes to oxidize the surface of resin substrate layer. Then, the multilayered substrate was immersed in a water bath for one minute with shaking. The procedure was repeated once more in the other water bath to wash the multilayered substrate. Then, the multilayered plate was immersed in an aqueous solution adjusted to contain 170 g/L of hydroxylamine sulfate and 80 g/L of sulfuric acid at 25° C. for five minutes, neutralized and reduced, washed with water and water was removed by blowing nitrogen gas.

3. Step for Formation of the Initiator Pattern

The initiator pattern was drawn with 0.3% aqueous solution of a coordination structure containing compound, 1-(2-aminoethyl)-2-methylimidazole in a desired wiring pattern with an ink jet printing apparatus on the surface of the resin substrate layer of aforementioned multilayered substrate. The treated plate was allowed to stand and dried in a nitrogen purged oven at 90° C. for 30 minutes.

4. Step for Electroless Plating

The dried multilayered substrate having the initiator pattern on the surface was immersed in a Pd salt containing plate catalytic solution adjusted at 60° C. and to contain ACTIVATOR MAT-1-A (made by C. Uyemura & Co. Ltd.) at 200 ml/L, ACTIVATOR MAT-1-B (made by C. Uyemura & Co. Ltd.) at 30 ml/L and sodium hydroxide at one gram/L for five minutes. Then, the multilayered substrate was similarly washed with water to activate the catalyst and immersed in a solution adjusted to contain REDUCER MRD-2-A (made by C. Uyemura & Co. Ltd.) at 18 ml/L and REDUCER MRD-2-C (made by C. Uyemura & Co. Ltd.) at 60 ml/L at 35° C. for five minutes to reduce catalyst for plating. Thus, the catalyst for plating was adsorbed as shown above and the surface roughness of the outermost insulating layer surface of the resultant multilayered substrate was determined. The surface roughness of pattern for drawn part showed Ra=41 nm and that without drawn part showed Ra=40 nm.

The resultant multilayered substrate was immersed in an electroless plating solution adjusted to contain THRU-CUP PRX-1-A (made by C. Uyemura & Co. Ltd.) at 150 ml/L, THRU-CUP PRX-1-B (made by C. Uyemura & Co. Ltd.) at 100 ml/L and THRU-CUP PRX-1-C (made by C. Uyemura & Co. Ltd.) at 20 ml/L and at 25° C. with blowing air for 15 minutes to cause electroless plating and washed with water in a similar manner as shown above to give a multilayered substrate with formed plating layer (metal pattern) in a desired pattern-like form. The thickness of the plating layer was 0.7 μm.

5. Growth Step of Plating Layer

Then, in order to increase the thickness of the plating layer (metal pattern), the multilayered substrate was immersed in a high speed electroless plating solution adjusted to contain 80 ml/L of THRU-CUP ELC-SP-A (made by C. Uyemura & Co. Ltd.), 20 ml/L of THRU-CUP ELC-SP-B (made by C. Uyemura & Co. Ltd.), 80 ml/L of THRU-CUP ELC-SP-C (made by C. Uyemura & Co. Ltd.) and 20 ml/L of THRU-CUP ELC-SP-D (made by C. Uyemura & Co. Ltd.) at 60° C. under blowing air for five hours to cause electroless plating to grow on the previously formed plating layer at 18 μm thickness. Furthermore, the plating layer was washed with water in a similar manner with that of the previous method to give a multilayer substrate with a desired patterned plating layer (metallic pattern) formed thereon. The total thickness of the plating layer was 18 μm. The multilayer substrate was immersed in a rust proof solution adjusted to contain AT-21 (made by C. Uyemura & Co. Ltd.) adjusted at 10 ml/L and at 25° C. for one minute and washed with water in a similar manner with that of the previous method and dried to give rust proof treatment.

6. Heat Treatment Step

The rust proof treated multilayered substrate was subjected to heat treatment by allowing standing in an oven in a nitrogen atmosphere at 170° C. for 30 minutes to give a multilayered circuit board having metal patterns on both sides. The roughness of the surface of the resin substrate layer of the resultant multilayered circuit board at the part without pattern was evaluated and found Ra=46 nm. Evaluation of adhesiveness and patterning of the resultant multilayered circuit board showed “good” adhesiveness and “excellent” patterning.

### Comparative example 1

A multilayered circuit board was obtained in a similar manner with that of example 1 except for no oxidation treatment using permanganic acid.

After adhesion of catalyst for plating, the surface roughness of the resin substrate layer (outermost insulating layer) before electroless plating was evaluated and showed Ra 29 nm and 24 nm for pattern drawn part and not drawn part, respectively.

Evaluation of surface roughness of insulating layer of the resultant multilayered circuit board without the pattern showed Ra=30 nm. Evaluation of adhesiveness and patterning of the resultant multilayered circuit board were “excellent” for patterning, however, “poor” for adhesiveness.

Comparison of the results of example 1 and comparative example 1 showed marked improvement in adhesiveness of plating layer by oxidation'treatment of resin substrate surface before formation of the initiator pattern. The partial plating process of the present invention and a manufacturing process of the multilayered circuit board require no roughing step of the resin substrate surface and showed little surface roughness of the resin substrate in an interface with the metal pattern. Therefore, the process of the present invention is suitable for manufacturing of multilayered circuit board to overcome the problems in the use of roughened resin substrate.

### INDUSTRIAL AVAILABILITY

The present invention provides a process for partial plating to give a partially plated resin substrate with excellent adhesiveness of metal pattern to resin substrate. Further, the present invention provides the partially plated resin substrate with excellent adhesiveness of the metal pattern to the resin substrate. Still further, the present invention provides a manufacturing process of a multilayered circuit board with excellent adhesiveness of the metal pattern (conductor circuit) with the resin substrate (insulating layer).

The partially plated resin substrate manufactured by the process of the present invention and resin parts such as multilayered circuit board with equipped the resin substrate layer having a partially plating layer are suitable for printed wiring boards used for semiconductor device mounted parts, various panel display, IC cards and photo-devices.

1. A partial plating process for forming patterned plating layer on a surface of a resin substrate, which comprises the following steps:
(1) subjecting said surface of said resin substrate to oxidation treatment,
(2) causing a compound, which has a structure capable of coordination to a metal atom or metal ion, to adhere in a patterned form on said oxidation-treated surface of said resin substrate to form an initiator pattern,
(3) forming a plating layer on said initiator pattern by electroless plating, and
(4) allowing said plating layer to grow to a desired thickness by electroless plating or electrolytic plating as needed.

2. A process according to claim 1, wherein said resin substrate is one obtained by forming a curable resin composition, which comprises an insulating resin and a curing agent, and curing said curable resin composition.

3. A process according to claim 2, wherein said insulating resin is at least one insulating resin selected from the group consisting of epoxy resins, maleimide resins, (meth)acrylic resins, dially phthalate resins, triazine resins, alicyclic olefin polymers, aromatic polyether polymers, benzocyclobutene polymers, cyanate ester polymers, liquid crystal polymers and polyimide resins.

4. A process according to claim 3, wherein said insulating resin is an alicyclic olefin polymer with a weight average molecular weight of from 10,000 to 1,000,000.

5. A process according to claim 1, wherein said oxidation treatment in step (1) is carried out by bringing an oxidizing compound into contact with said surface of said resin substrate or plasma treatment.

6. A process according to claim 1, wherein in step (1), said oxidation treatment is carried out such that said surface of said resin substrate is provided with a surface roughness, Ra (JIS B-0601), of not greater than 200 nm after said oxidation treatment.

7. A process according to claim 1, wherein said compound having the structure capable of coordination to said metal atom or metal ion is at least one compound having an unshared electron pair selected from the group consisting of organic compounds having an amino group, thiol group, carboxyl group or cyano group, and heterocyclic compounds having a nitrogen atom, oxygen atom or sulfur atom.

8. A process according to claim 7, wherein said compound having the structure capable of coordination to said metal atom or metal ion is an imidazole, pyrazole, triazole or triazine having an amino group, thiol group, carboxyl group or cyano group.

9. A process according to claim 1, further comprising a step of subjecting said resin substrate with patterned plating layer formed thereon to heat treatment.

10. A partially plated resin substrate comprising a resin substrate with an oxidation treated surface and a plating layer formed on said oxidation-treated surface via an initiator pattern composed of a compound, which has a structure capable of coordination to a metal atom or metal ion, adhered in a patterned form.

11. A process for manufacturing a multilayered circuit board, which comprises the following steps:
(I) forming a resin substrate layer over a surface of an inner layer substrate, which carries thereon an insulating layer with a conductor circuit formed on a surface thereof such that said conductor circuit is covered with said resin substrate layer,
(II) subjecting said surface of said resin substrate layer to oxidation treatment,
(III) causing a compound, which has a structure capable of coordination to a metal atom or metal ion, to adhere in a form of a pattern of said conductor circuit on said oxidation-treated surface of said resin substrate layer to form an initiator pattern,
(IV) forming a plating layer on said initiator pattern by electroless plating, and
(V) allowing said plating layer to grow to a desired thickness by electroless plating or electrolytic plating as needed.

12. A process according to claim 11, wherein in said step (I) said resin substrate layer is formed by forming a layer of a curable resin composition, which comprises an insulating resin and a curing agent, such that said conductor circuit is covered by said layer of said curable resin composition, and then curing said curable resin composition.

13. A process according to claim 12, wherein in said step (I) said resin substrate layer is formed by laminating a film of a curable resin composition, which comprises an insulating resin and a curing agent, to form a layer of said curable resin composition such that said conductor circuit is covered by said layer of said curable resin composition, and then curing said curable resin composition.

14. A process according to claim 11, wherein said insulating resin is at least one insulating resin selected from the group consisting of epoxy resins, maleimide resins, (meth)acrylic resins, dially phthalate resins, triazine resins, alicyclic olefin polymers, aromatic polyether polymers, benzocyclobutene polymers, cyanate ester polymers, liquid crystal polymers and polyimide resins.

15. A process according to claim 14, wherein the insulating resin is an alicyclic olefin polymer with a weight average molecular weight of from 10,000 to 1,000,000.

16. A process according to claim 11, wherein the oxidation treatment in step (II) is carried out by bringing an oxidizing compound into contact with said surface of said resin substrate or plasma treatment.

17. A process according to claim 11, wherein oxidation treatment is carried such that said surface of said resin substrate is provided with a surface roughness, Ra (JIS B-0601) of not greater than 200 nm after said oxidation treatment.

18. A process according to claim 11, wherein said compound having the structure capable of coordination to said metal atom or metal ion is at least one compound having an unshared ion pair selected from the group consisting of organic compounds having an amino group, thiol group, carboxyl group or cyano group, and heterocyclic compounds having a nitrogen atom, oxygen atom or sulfur atom.

19. A process according to claim 11, further comprising a step of subjecting said resin substrate with pattered plating layer formed thereon to heat treatment.

20. A process according to claim 11, wherein steps similar to steps (I) to (V) are repeated as needed until one or more resin substrate layers, each of which comprises an inner layer substrate and a plating layer formed in a form of a pattern of a conductor circuit formed on at least one side of said inner layer substrate, are formed one over the other as many as desired.
